(19) United States
(12) Patent Application Publication
(10) Pub. No.: US 2026/0082510 A1
(43) Pub. Date: Mar. 19, 2026

(54) DIRECT LIQUID COOLING SYSTEMS WITH COOLANT LEAKAGE DETECTION

(71) Applicant: Super Micro Computer, Inc., San Jose, CA (US)

(72) Inventors: Mark YANG, HsinChu (TW); Ming JIAN, Bade (TW)

(21) Appl. No.: 18/884,494

(22) Filed: Sep. 13, 2024

(51) Int. Cl. H05K 7/20; G01M 3/00; G06F 1/20

(52) U.S. Cl. CPC H05K 7/20272; G01M 3/002; G06F 1/20; H05K 7/20254

(57) ABSTRACT

Systems and methods for detecting coolant leakage in direct liquid cooling systems are disclosed. Liquid coolant is flowed through cold plates that are attached to adjacent processors. Sensor readings of the processors are formed into a differential signal. Distribution of the differential signal is determined. Leakage of the liquid coolant is detected from the distribution of the differential signal.

### TECHNICAL FIELD

The present disclosure is directed to direct liquid cooling of electronic components.

### BACKGROUND

Direct liquid cooling, also known as direct-to-chip cooling, is a cooling system in which a liquid coolant is circulated directly over the surface of an integrated circuit (IC) chip to dissipate heat efficiently. Direct liquid cooling allows for precise temperature control of specific high-heat components like central processing units (CPUs), graphics processing units (GPUs), and other processors, directly addressing the areas that generate the most heat. This targeted approach can lead to more efficient cooling and better performance optimization for those critical components. However, direct liquid cooling also has a higher risk of leaks at the interfaces where the liquid coolant is circulated, which could damage sensitive components.

Conventional methods for detecting coolant leakage in direct liquid cooling systems typically involve using specialized sensors or specific chemicals, such as fluorescent dyes, to identify leaks. Both approaches face challenges, particularly in managing sensor bias and noise when measuring individual IC chips being cooled. These challenges not only increase design costs but also complicate efforts to achieve the desired reliability.

### BRIEF SUMMARY

In one embodiment, a method of detecting coolant leakage in a direct liquid cooling system includes receiving temperature readings of a first processor that is attached to a first cold plate. Temperature readings of a second processor that is attached to a second cold plate are received. The first processor is adjacent to the second processor on a circuit board. A differential temperature signal is formed by subtracting the temperature readings of the first processor from the temperature readings of the second processor. A distribution of the differential temperature signal is determined. Leakage of liquid coolant flowing through either the first cold plate or the second cold plate is detected based at least on the distribution of the differential temperature signal.

In another embodiment, a computer comprises at least one processor and a memory, the memory stores instructions that when executed by the at least one processor cause the computer to: receive sensor readings of a first processor that is attached to a first cold plate; receive sensor readings of a second processor that is attached to a second cold plate, wherein the first and second processors are adjacent on a circuit board; form the sensor readings of the first processor and the sensor readings of the second processor into a differential signal; determine a distribution of the differential signal; and detect leakage of liquid coolant flowing through either the first cold plate or the second cold plate based at least on the distribution of the differential signal.

In yet another embodiment, a method of detecting coolant leakage in a direct liquid cooling system includes receiving sensor readings of a first processor and sensor readings of a second processor. The first processor and the second processor are adjacent on a circuit board. The sensor readings of the first and second processors are formed into a differential signal. A distribution of the differential signal is determined. Leakage of a liquid coolant that is flowing either through a first cold plate that is attached to the first processor or through a second cold plate that is attached to the second processor is detected based at least on the distribution of the differential signal.

These and other features of the present disclosure will be readily apparent to persons of ordinary skill in the art upon reading the entirety of this disclosure, which includes the accompanying drawings and claims.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 shows a block diagram of a direct liquid cooling system with coolant leakage detection, in accordance with an embodiment of the present invention.

FIGS. 2-4 show a flow diagram of a method of detecting coolant leakage, in accordance with an embodiment of the present invention.

FIGS. 5 and 6 show graphs of results of simulations of coolant leakage scenarios, in accordance with an embodiment of the present invention.

FIG. 7 shows a flow chart of a method of detecting coolant leakage, in accordance with an embodiment of the present invention.

FIG. 8 shows a block diagram of a computer that hosts a leak detector, in accordance with an embodiment of the present invention.

### DETAILED DESCRIPTION

In the present disclosure, numerous specific details are provided, such as examples of systems, components, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

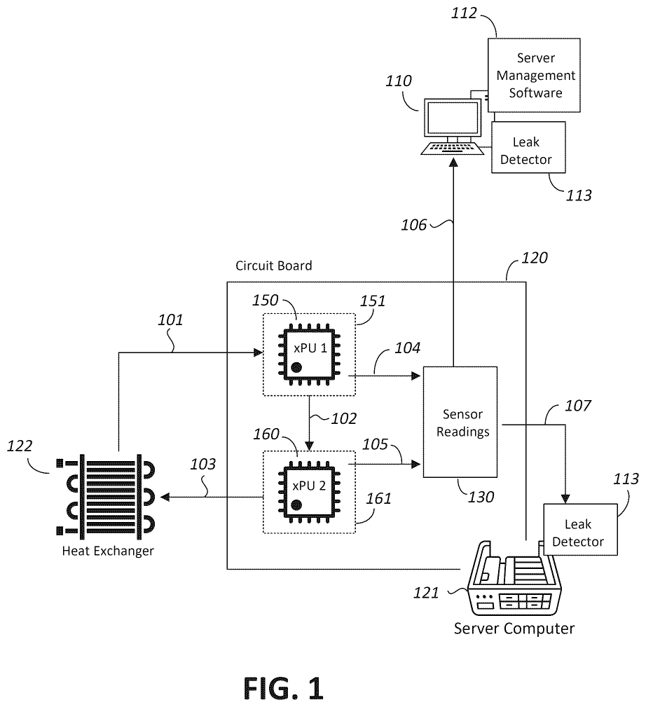

FIG. 1 shows a block diagram of a direct liquid cooling system with coolant leakage detection, in accordance with an embodiment of the present invention. In the example of FIG. 1, processors 150 and 160 are adjacent on a circuit board 120, such as a printed circuit board (PCB). The processors 150 and 160 may be central processing units (CPUs), graphics processing units (GPUs), tensor processing units (TPUs), or another type of processor. The processors 150 and 160 are cooled by direct liquid cooling, which involves attaching a cold plate to each processor and flowing liquid coolant through the cold plate to transfer heat from the processor to the coolant.

In the example of FIG. 1, a cold plate 151 is attached to the processor 150, and a cold pate 161 is attached to the processor 160. A liquid coolant enters an inlet of the cold plate 151 (see arrow 101), exits from an outlet of the cold plate 151 to enter an inlet of the cold plate 161 (see arrow 102), and exits from an outlet of the cold plate 161 (see arrow 103). The heated coolant from the outlet of the cold plate 161 is cooled by a heat exchanger 122. The cold plates 151 and 161 share the same cooling loop in the example of FIG. 1. However, the cold plates 151 and 161 may also have separate cooling loops. Pumps, cooling distribution units (CDUs), and other cooling components not necessary to the understanding of the invention are not shown.

In one embodiment, sensor readings 130 are temperature readings of the processor 150 (see arrow 104) and processor 160 (see arrow 105). The temperature of each of the processors 150 and 160 may be read from the processors themselves (i.e., from internal temperature sensors), corresponding temperature sensors that are external to the processors 150 and 160, corresponding ambient temperature sensors, etc. The processors 150 and 160 are adjacent in that they are disposed next to each other in a side-by-side arrangement on the circuit board 120. In one embodiment, the circuit board 120 is a motherboard of a server computer 121.

The sensor readings 130 may be collected as sensor data records (SDR) in accordance with the Intelligent Platform Management Interface (IPMI) standard and stored in non-volatile memory of a Baseboard Management Controller (BMC) on the circuit board 120. As can be appreciated the sensor readings 130 may also be stored in other types of memory or storage device.

A server management software 112 running on a computer 110 may obtain the sensor readings 130 over a computer network (see arrow 106). In the example of FIG. 1, the server management software 112 includes a leak detector 113 for detecting coolant leakage in a processor, i.e., leakage of liquid coolant that flows through the cold plate attached to the processor. The leak detector 113 may be a stand-alone software module or integrated with the sever management software 112. As can be appreciated, the leak detector 113 may also be implemented in hardware or combination of hardware and software. The leak detector 113 may receive the sensor readings 130 directly or by way of the server management software 112. The leak detector 113 may also be running on the server computer 121. In that case, the leak detector 113 locally receives the sensor readings 130 (see arrow 107).

In one embodiment, the leak detector 113 is configured to detect coolant leakage by receiving sensor readings of the processors 150 and 160, forming the sensor readings into a differential signal, determining a distribution of the differential signal, and detecting coolant leakage in the processor 150 or the processor 160 based on the distribution of the differential signal. The leak detector 113 may further process the sensor readings to identify which processor is experiencing coolant leakage, determine if both processors are simultaneously experiencing coolant leakage, and detect any false positives.

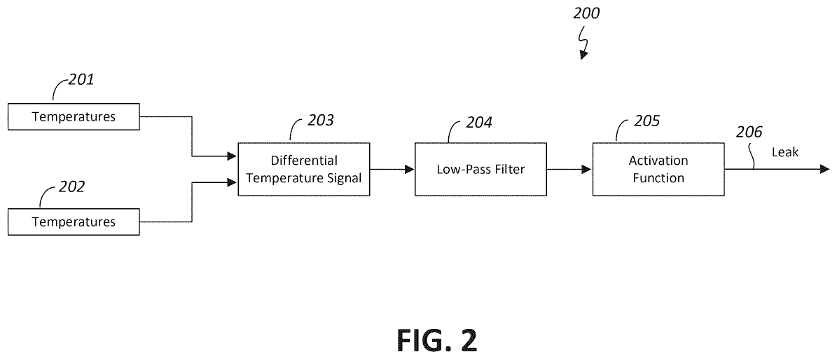

FIGS. 2-4 show a flow diagram of a method 200 of detecting coolant leakage, in accordance with an embodiment of the present invention. The method 200 may be performed by the leak detector 113. The sensor readings 130 are temperature readings in the example of FIGS. 2-4.

Referring first to FIG. 2, the temperatures 201 are temperature readings of the processor 150, whereas the temperatures 202 are temperature readings of the processor 160. The temperatures 201 and 202 are obtained from the same type of temperature sensor, e.g., both from IPMI SDR temperature readings, both from ambient temperature sensors, or both from external sensors attached to the processors or cold plates. The temperatures 201 form a single-ended temperature signal of the temperature readings of the processor 150, and the temperatures 202 form a single-ended temperature signal of the temperature readings of the processor 160. The temperatures 201 and 202 are aligned by timestamp.

In the example of FIG. 2, the temperatures 201 and 202 are formed into a differential temperature signal 203, where each point of the differential temperature signal 203 represents a difference between concurrent temperature readings of the processors 150 and 160. More particularly, the temperatures 201 and temperatures 202 are aligned in time, and the temperatures 202 are subtracted from the temperatures 201 (or vice versa) to generate the differential temperature signal 203.

Under normal operating conditions, where neither the processor 150 nor the processor 160 experiences coolant leakage, the differential temperature signal 203 distributes stochastically within a narrow dynamic range and with a mean value of approximately zero. However, when coolant leakage occurs, the distribution of the differential temperature signal 203 will deviate noticeably from its normal pattern, exhibiting characteristics inconsistent with a stochastic signal, and will have an apparent non-zero mean value. In one embodiment, this deviation from normal operating conditions is detected by applying a low-pass filter followed by an activation function to the differential temperature signal 203.

In the example of FIG. 2, the differential temperature signal 203 is passed through a low-pass filter 204 to remove high-frequency noise or fluctuations from the differential temperature signal 203 that may not be relevant to detecting coolant leakage. Advantageously, the slope of the low-pass filter 204 does not necessarily have to be steep. An activation function 205 is thereafter applied to the low-pass-filtered signal, i.e., output of the low-pass filter 204. The activation function 205 outputs a signal that indicates whether or not there is coolant leakage in the processor 150 or the processor 160. The activation function 205 may be a step function, for example. In one embodiment, the activation function 205 asserts a leak signal (see arrow 206) when the low-pass-filtered signal is equal to or greater than a predetermined threshold, and de-asserts the leak signal when the low-pass-filtered signal is less than the predetermined threshold. In one embodiment, an asserted signal is at a logical HIGH, and a de-asserted signal is at a logical LOW. An asserted leak signal indicates that either the processor 150 or the processor 160 is experiencing coolant leakage.

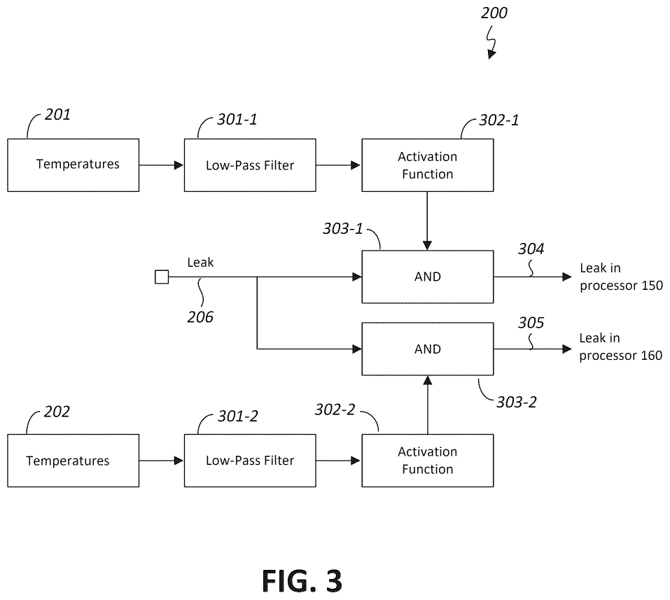

In the example of FIG. 2, the leak signal output of the activation function 205 indicates detection of coolant leakage but does not identify which of the processors 150 and 160 is leaking. The method 200 may continue to FIG. 3 to identify which of the processors is leaking when coolant leakage is detected.

Referring to FIG. 3, the temperatures 201 are temperature readings of the processor 150 and the temperatures 202 are temperature readings of the processor 160 as previously explained with reference to FIG. 2. In the example of FIG. 3, a low-pass filter 301 (i.e., 301-1, 301-2) is the same as the low-pass filter 204 (shown in FIG. 2), except that the low-pass filter 301 is configured for a single-ended temperature signal (i.e., temperature readings of a single processor). Similarly, the activation function 302 (i.e., 302-1, 302-2) is the same as the activation function 205, except the activation function 302 is configured for a single-ended temperature signal.

The DC components of the temperatures 201 and 202 are removed before the temperatures 201 and 202 are low-pass filtered by a corresponding low-pass filter 301. A corresponding activation function 302 is then applied to the low-pass-filtered signal. In one embodiment, an activation function 302 asserts (i.e., at a logical HIGH) its output signal when the low-pass-filtered signal is equal to or greater than a predetermined threshold, and de-asserts (i.e., at a logical LOW) its output signal when the low-pass-filtered signal is less than the predetermined threshold. The activation function 302 asserts its output signal when a corresponding single-ended temperature signal indicates a coolant leakage in the corresponding processor.

The leak signal (shown in FIGS. 2 and 3; see arrow 206) is asserted when coolant leakage is detected in either the processor 150 or the processor 160. A logical AND operation 303-1 is applied to the leak signal and the output of the activation function 302-1. The output of the logical AND operation 303-1 (see arrow 304) is asserted, indicating detection of a coolant leakage in the processor 150, when both the leak signal and the output of the activation function 302-1 are asserted. Similarly, a logical AND operation 303-2 is applied to the leak signal and the output of the activation function 302-2. The output of the logical AND operation 303-2 (see arrow 305) is asserted, indicating detection of a coolant leakage in the processor 160, when both the leak signal and the output of the activation function 302-2 are asserted. It is to be noted that coolant leakage in a processor may be detected from the output of its corresponding activation function 302. In the example of FIG. 3, the logical AND operation on the output of an activation function 302 and the leak signal advantageously enhances detection sensitivity and reduces false positives.

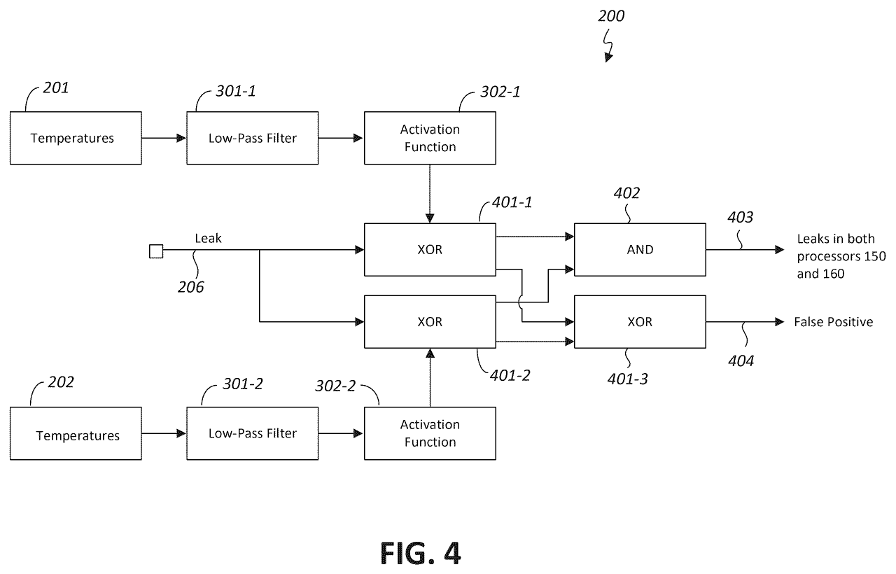

The method 200 may continue to FIG. 4 to cover scenarios where both of the processors 150 and 160 are experiencing coolant leakage, and to detect false positives. The operations of FIG. 4 are performed when coolant leakage is not detected from the differential temperature signal 203.

FIG. 4 shows the previously-explained temperatures 201 and 202, low-pass filters 301-1 and 301-2, and activation functions 302-1 and 302-2. The DC components of the temperatures 201 and 202 are removed before passing them through the low-pass filters 301-1 and 301-2, respectively. The output of the activation function 302-1 is asserted when coolant leakage is detected in the processor 150, and the output of the activation function 302-2 is asserted when coolant leakage is detected in the processor 160.

The leak signal (shown in FIGS. 2-4; arrow 206) indicates whether or not coolant leakage is detected from the differential temperature signal 203. A logical XOR operation 401-1 is applied to the leak signal and the output of the activation function 302-1, and a logical XOR operation 401-2 is applied to the leak signal and the output of the activation function 302-2. The output of the logical XOR operation 401-1 is asserted when the leak signal is de-asserted and the output of the activation function 302-1 is asserted, meaning coolant leakage is not detected from the differential temperature signal 203, but coolant leakage is detected from the single-ended temperature signal of the processor 150. Similarly, the output of the logical XOR operation 401-2 is asserted when the leak signal is de-asserted and the output of the activation function 302-2 is asserted, meaning coolant leakage is not detected from the differential temperature signal 203, but coolant leakage is detected from the single-ended temperature signal of the processor 160.

A logical AND operation 402 is applied to the outputs of the logical XOR operations 401-1 and 401-2. The output of the logical AND operation 402 (see arrow 403) is asserted when coolant leakage is detected in both processors. Specifically, the processors 150 and 160 are detected to be leaking simultaneously when the outputs of the logical XOR operations 401-1 and 401-2 are both asserted. In other words, coolant leakage in both processors is detected when coolant leakage is not detected from the differential temperature signal 203 but coolant leakage is detected from the single-ended temperature signals of both processors.

When there is coolant leakage in both the processors 150 and 160, the differential temperature signal 203 will distribute stochastically in a narrow dynamic range, similar to when there is no coolant leakage in either processor. Detecting coolant leakage from each of the single-ended temperature signals when the differential temperature signal does not indicate a coolant leakage advantageously addresses the relatively rare scenario where the processors 150 and 160 simultaneously experience coolant leakage, which may result in cancelling out in the differential temperature signal and thereby impact the leakage detection.

A false positive is an occurrence of an erroneous indication of coolant leakage. A false positive is detected when coolant leakage is not detected from the differential temperature signal 203, but coolant leakage is detected from only one of the single-ended temperature signal of the processor 150 and the single-ended temperature signal of the processor 160. The output of the logical XOR operation 401-3 (see arrow 404) is asserted, indicating a false positive, when either (a) the output of the logical XOR operation 401-1 is asserted and the output of the logical XOR operation 401-2 is de-asserted, or (b) the output of the logical XOR operation 401-1 is de-asserted and the output of the logical XOR operation 401-2 is asserted.

A corrective action may be performed in response to detecting coolant leakage in either processor or occurrence of a false positive. The corrective action may include raising an alert, such as displaying a message on a graphical user interface of the server management software 112, recording the detection of the coolant leakage in a log, sending a notification to an administrator (or other data center personnel), sending a signal to another component, etc. The corrective action advantageously allows data center personnel to address the coolant leakage or false positive.

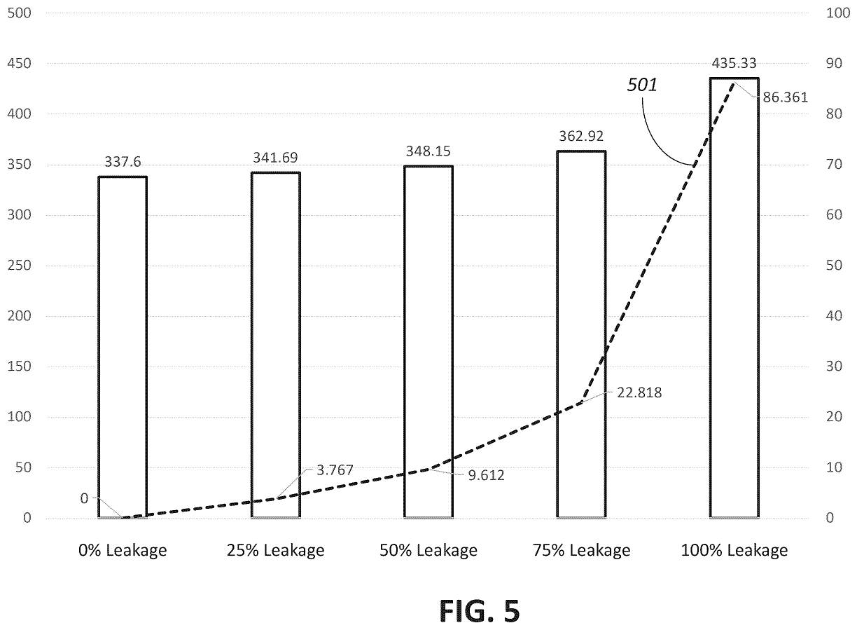

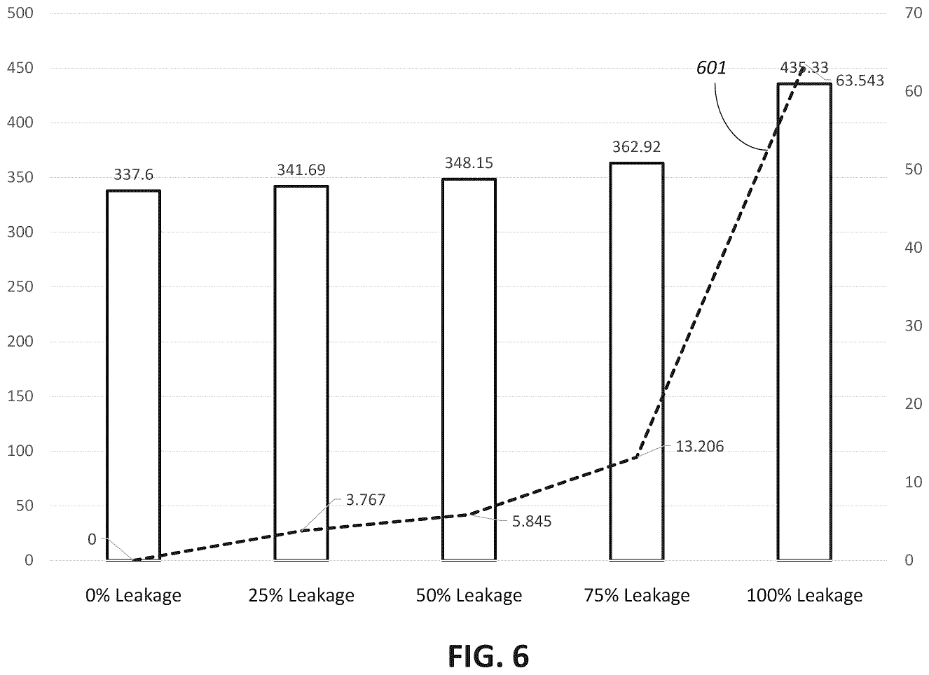

FIGS. 5 and 6 show graphs of the results of simulations of coolant leakage scenarios, in accordance with an embodiment of the present invention. The simulation results are for two adjacent CPUs, where neither CPU experiences coolant leakage (“0% leakage”), one of the CPUs experiences 25% coolant leakage (“25% leakage”), one of the CPUs experiences 50% coolant leakage (“50% leakage”), one of the CPUs experiences 75% coolant leakage (“75% leakage”), and one of the CPUs experiences 100% coolant leakage (“100% leakage”). The percentage leakage represents the proportion of total liquid coolant that should be flowing but is lost due to the leak. For example, at 25% leakage, 25% of the liquid coolant that should be flowing is lost due to the leak; at 100% leakage, all of the liquid coolant is leaking out. The leakage is assumed to be occurring at the cold plate. The simulations were performed using ANSYS Fluent™ simulation software.

It should be noted that although the assumed geometry of the cold plate and simulation parameters affect the simulation results, the slope of the temperature difference measurements and the gradient behavior of the temperature difference measurements will remain consistent and serve to enhance the sensitivity of leakage detection in a direct liquid cooling system. Also, while the simulation is modeled on adjacent CPUs, the same conclusions apply to other types of processors, including GPUs.

In FIG. 5, the vertical axis represents temperature in Kelvin, each bar graph indicates the highest temperature reading among the two CPUs, and the plot 501 represents the temperature difference between the two CPUs. For example, the highest temperature reading amongst the two CPUs when there is no leak is 337.6 K, the highest temperature reading amongst the two CPUs when one of the CPUs experiences 25% coolant leakage is 341.69 K, etc. Note the increasing slope of the plot 501 of temperature difference between the two CPUs as the leakage increases.

In FIG. 6, the vertical axis represents temperature in Kelvin, each bar graph indicates the highest temperature reading among the two CPUs, and the plot 601 represents the temperature gradient of the two CPUs, i.e., gradient of temperature difference between the two CPUs. The bar graphs are the same in both FIGS. 5 and 6. Similar to the plot 501 of temperature difference, note the increasing slope of the plot 601 of temperature gradient as the leakage increases. The simulations of FIGS. 5 and 6 demonstrate that the distribution of differential temperature signal of two adjacent CPUs may be used to detect coolant leakage.

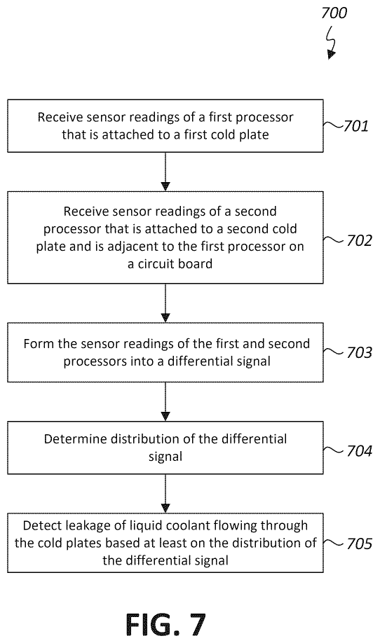

FIG. 7 shows a flow chart of a method 700 of detecting coolant leakage, in accordance with an embodiment of the present invention. The method 700 may be performed by the leak detector 113.

In step 701, sensor readings of a first processor that is attached to a first cold plate are received.

In step 702, sensor readings of a second processor that is attached to a second cold plate are received. The first processor is disposed adjacent to the second processor on a circuit board, such as a PCB that serves as a motherboard of a server computer. In one embodiment, the sensor readings are temperature readings. The temperature readings may be internal readings, i.e. taken from the processors. The temperature readings may also be taken by corresponding ambient temperature sensors that are external but in closed proximity to the processors. As can be appreciated, embodiments of the present invention are equally applicable to other types of sensor readings that are indicative of coolant leakage. For example, the sensor readings may be humidity readings of adjacent processors.

In step 703, the sensor readings of the first processor and the sensor readings of the second processor are formed into a differential signal. The differential signal may be formed by subtracting sensor readings of the first processor from concurrent sensor readings of the second processor.

In step 704, the distribution of the differential signal is determined. In one embodiment, the distribution of the differential signal is determined by applying a low-pass filter to the differential signal to generate a low-pass-filtered signal and applying an activation function to the low-pass-filtered signal. The activation function may be a step function with a predetermined threshold, for example.

In step 705, leakage of liquid coolant flowing through the first cold plate or the second cold plate is detected based at least on the distribution of the differential signal. For example, the low-pass-filtered signal may be compared to the predetermined threshold of the step function. In that example, leakage of liquid coolant is detected when the low-pass-filtered signal is equal to or greater than the predetermined threshold.

Leakage of liquid coolant flowing through a particular one of the first cold plate and the second cold plate is detected when the differential signal indicates leakage of the liquid coolant flowing through either the first cold plate or the second plate, and only one of a single-ended signal of sensor readings of the first processor and a single-ended signal of sensor readings of the second processor indicates leakage of liquid coolant flowing through the corresponding cold plate.

Leakage of liquid coolant flowing through the first cold plate and the second cold plate is detected when the differential signal does not indicate leakage of liquid coolant flowing through either the first cold plate or the second cold plate, but the single-ended signal of sensor readings of the first processor and the single-ended signal of sensor readings of the second processor both indicate leakage of liquid coolant flowing through the first cold plate and the second cold plate.

A false positive is detected when the differential signal does not indicate leakage of coolant flowing through either the first cold plate or the second cold plate, but only one of the single-ended signal of sensor readings of the first processor and the single-ended signal of sensor readings of the second processor indicates leakage of liquid coolant flowing through the corresponding cold plate.

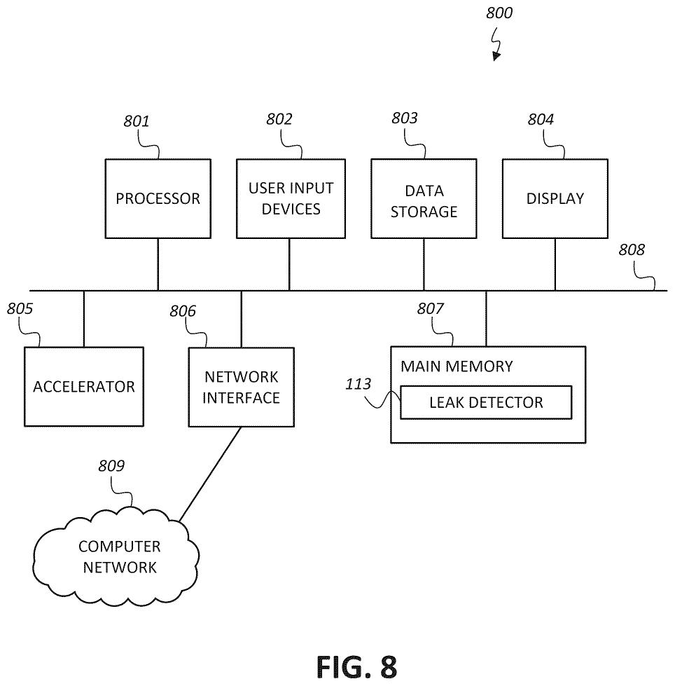

FIG. 8 shows a block diagram of a computer 800 that may host the leak detector 113, in accordance with an embodiment of the present invention. The computer 800 may include one or more processors 801, one or more user input devices 802 (e.g., keyboard, mouse), one or more data storage devices 803 (e.g., hard drive, optical disk, solid state drive), a display screen 804 (e.g., liquid crystal display, flat panel monitor), one or more accelerators 805 (e.g., graphics processing unit (GPU), neural processing unit (NPU)), a computer network interface 806 (e.g., network adapter, modem), and a main memory 807 (e.g., random access memory). The computer 800 may have one or more buses 808 coupling its various components. The computer network interface 806 may be coupled to a computer network 809. The computer 800 may have fewer or more components to meet the needs of a particular application.

The computer 800 is a particular machine as programmed with one or more software modules, comprising instructions stored non-transitory in the main memory 807 for execution by at least one processor 801 to cause the computer 800 to perform corresponding programmed steps. In the example of FIG. 8, the main memory 807 stores instructions of the leak detector 113.

Systems and methods for detecting coolant leakage in direct liquid cooling systems have been disclosed. While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method of detecting coolant leakage, the method comprising:
receiving temperature readings of a first processor that is attached to a first cold plate;
receiving temperature readings of a second processor that is attached to a second cold plate, wherein the first processor is adjacent to the second processor on a circuit board;
forming a differential temperature signal by subtracting the temperature readings of the first processor from the temperature readings of the second processor;
determining a distribution of the differential temperature signal; and
detecting leakage of a liquid coolant flowing through either the first cold plate or the second cold plate based at least on the distribution of the differential temperature signal.

2. The method of claim 1, wherein determining the distribution of the differential temperature signal comprises:
applying a low-pass filter on the differential temperature signal to generate a low-pass-filtered signal.

3. The method of claim 2, further comprising:
detecting leakage of the liquid coolant flowing through either the first cold plate or the second plate responsive to the low-pass-filtered signal exceeding a threshold.

4. The method of claim 3, wherein the threshold is that of an activation function.

5. The method of claim 1, wherein the temperature readings of the first and second processors are taken by internal temperature sensors of the first and second processors.

6. The method of claim 1, wherein the temperature readings of the first and second processors are taken by ambient temperature sensors that are external to the first and second processors.

7. The method of claim 1, wherein the first and second processors are central processing units (CPUs) or graphics processing units (GPUs).

8. A computer comprising at least one processor and a memory, the memory storing instructions that when executed by the at least one processor cause the computer to:
receive sensor readings of a first processor that is attached to a first cold plate;
receive sensor readings of a second processor that is attached to a second cold plate, wherein the first and second processors are adjacent on a circuit board;
form the sensor readings of the first processor and the sensor readings of the second processor into a differential signal;
determine a distribution of the differential signal; and
detect leakage of a liquid coolant flowing through either the first cold plate or the second cold plate based at least on the distribution of the differential signal.

9. The computer of claim 8, wherein the circuit board is a motherboard of a server computer.

10. The computer of claim 9, wherein the sensor readings of the first processor and the sensor readings of the second processor are received in the computer over a computer network.

11. The computer of claim 10, wherein the sensor readings of the first processor and the sensor readings of the second processor are sensor data records received by the computer in accordance with the Intelligent Platform Management Interface (IPMI) standard.

12. The computer of claim 11, wherein the sensor data records are stored in non-volatile memory of a Baseboard Management Controller (BMC) that is mounted on the circuit board.

13. The computer of claim 8, wherein the sensor readings of the first processor and the sensor readings of the second processor are temperature readings taken by ambient temperature sensors that are external to the first and second processors.

14. The computer of claim 8, wherein the sensor readings of the first processor and the sensor readings of the second processor are temperature readings taken by internal temperature sensors of the first and second processors.

15. A method of detecting coolant leakage in a direct liquid cooling system, the method comprising:
receiving sensor readings of a first processor;
receiving sensor readings of a second processor that is adjacent to the first processor on a circuit board;
forming the sensor readings of the first and second processors into a differential signal;
determining a distribution of the differential signal; and
detecting leakage of a liquid coolant that is flowing either through a first cold plate that is attached to the first processor or through a second cold plate that is attached to the second processor based at least on the distribution of the differential signal.

16. The method of claim 15, wherein the sensor readings of the first processor and the sensor readings of the second processor comprise temperature readings.

17. The method of claim 15, wherein determining the distribution of the differential signal comprises:
applying a low-pass filter to the differential signal to generate a low-pass-filtered signal; and
applying an activation function to the low-pass-filtered signal.

18. The method of claim 15, further comprising:
detecting leakage of the liquid coolant flowing through the first cold plate but not through the second cold plate responsive to detecting leakage of the liquid coolant flowing either through the first cold plate or through the second cold plate based on the distribution of the differential signal, detecting leakage of the liquid coolant flowing through the first cold plate from a single ended signal of the sensor readings of the first processor, and not detecting leakage of the liquid coolant flowing through the second plate from a single-ended signal of the sensor readings of the second processor.
